(19) United States
(12) Patent Application Publication
(10) Pub. No.: US 2026/0324381 A1
(43) Pub. Date: Oct. 15, 2026

(54) METHOD TO FABRICATE SWITCHABLE INTERCONNECTS

(71) Applicant: UCHICAGO ARGONNE, LLC, Chicago, IL (US)

(72) Inventor: Angel YANGUAS-GIL, Northbrook, IL (US)

(73) Assignee: UCHICAGO ARGONNE, LLC, Chicago, IL (US)

(21) Appl. No.: 19/532,317

(22) Filed: Feb. 6, 2026

Related U.S. Application Data
(60) Provisional application No. 63/785,953, filed on Apr. 9, 2025.

(51) Int. Cl. H10W 20/00

(52) U.S. Cl. CPC H10W 20/0595

(57) ABSTRACT

A method for fabricating an active interconnect can include etching a base surface of an interconnect positioned within a dielectric layer. The method can include depositing a layer on the base surface of the interconnect, sidewalls of the interconnect, and a base surface of the dielectric layer. The method can include removing a portion of the layer from the base surface. The method can include depositing a capping layer on a surface of the layer, encapsulating the layer within the interconnect.

### CROSS-REFERENCE TO RELATED APPLICATIONS

This application claims priority to U.S. Provisional Patent Application No. 63/785,953, filed on Apr. 9, 2025, which is incorporated herein by reference in its entirety for any and all purposes.

### STATEMENT OF GOVERNMENT INTEREST

This invention was made with government support under Contract No. DE-AC02-06CH11357 awarded by the United States Department of Energy to UChicago Argonne, LLC, operator of Argonne National Laboratory. The government has certain rights in the invention.

### FIELD OF DISCLOSURE

The present disclosure relates generally to reconfigurable, resilient architectures for on chip processing in microelectronics. Specifically, the current disclosure relates to systems and methods for fabricating switchable interconnects.

### SUMMARY

At least one aspect of the present disclosure relates to a method of forming a functional device. The method includes depositing a layer on the base surface of the interconnect, sidewalls of the interconnect, and a base surface of the dielectric layer. The method includes removing a portion of the layer from the base surface. The method includes depositing a capping layer on a surface of the layer, encapsulating the layer within the interconnect.

In some implementations, the layer is a first layer, and the method includes after removing the portion of the first layer, depositing a second layer on a surface of the first layer and the base surface of the dielectric layer, removing a portion of the second layer from the base surface of the dielectric layer, and depositing the capping layer on a surface of the second layer, encapsulating the first and second layers within the interconnect. In some implementations, the base surface of the interconnect is etched using a blanket etching process, a selective etching process, or a combination of a blanket etching and selective etching process. In some implementations, the layer is added to the surface of the interconnect using atomic layer deposition (ALD) or chemical vapor deposition (CVD).

In some implementations, the capping layer and the interconnect are included of a same metal. In some implementations, the method includes before etching the base surface of the interconnect, adding a protective layer to the base surface of the dielectric layer. In some implementations, the method includes after depositing the capping layer on the surface of the layer, removing the protective layer from the base surface of the dielectric layer. In some implementations, the functional device is configured to isolate a part of a circuit. In some implementations, the functional device is configured to reconfigure a part of a circuit.

At least another aspect of the present disclosure relates to a method of forming a functional device. The method includes etching a base surface of an interconnect positioned within a dielectric layer. The method includes depositing a layer to the base surface using a selective deposition process. The method includes depositing a capping layer on a surface of the layer, encapsulating the layer within the interconnect.

In some implementations, the method includes before depositing the layer to the base surface of the interconnect, depositing a deposition-inhibiting material to sidewalls of the interconnect. In some implementations, the deposition-inhibiting material includes small molecule inhibitors.

In some implementations, the layer is a first layer, and the method includes after depositing the first layer to the base surface of the interconnect, depositing a second layer on a surface of the first layer, and depositing the capping layer on a surface of the second layer, encapsulating the deposited first and second layers within the interconnect. In some implementations, depositing the second layer on the surface of the first layer includes depositing the second layer on the base surface of the interconnect, sidewalls of the interconnect, and a base surface of the dielectric layer, and removing a portion of the second layer from the sidewalls or the base surface of the dielectric layer.

In some implementations, the method includes before depositing the second layer on the surface of the first layer, depositing a deposition-inhibiting material to sidewalls of the interconnect. In some implementations, the method includes before etching the base surface of the interconnect, adding a protective layer to a base surface of the dielectric layer. In some implementations, the method includes after depositing the capping layer on the surface of the layer, removing the protective layer from the base surface of the dielectric layer.

At least another aspect of the present disclosure relates to a method of forming a functional device. The method includes adding a protective layer to a base surface of a dielectric layer, wherein an interconnect is positioned within the dielectric layer. The method includes etching a base surface of an interconnect positioned within a dielectric layer. The method includes depositing a layer to the base surface of the interconnect using one of a (a) conformal process or (b) a selective deposition process. The method includes depositing a capping layer on a surface of the layer, encapsulating the layer within the interconnect. The method includes removing the protective layer from the base surface of the dielectric layer.

In some implementations, the layer is a first layer, and the method includes after depositing the first layer to the base surface of the interconnect, depositing a second layer on a surface of the first layer, and depositing the capping layer on a surface of the second layer, encapsulating the deposited first and second layers within the interconnect. In some implementations, the techniques described herein relate to a method, wherein the second layer is deposited using one of a (a) conformal process or (b) a selective deposition process.

This summary is illustrative only and is not intended to be in any way limiting. Other aspects, inventive features, and advantages of the devices or processes described herein will become apparent in the detailed description set forth herein, taken in conjunction with the accompanying figures, wherein like reference numerals refer to like elements.

### BRIEF DESCRIPTION OF DRAWINGS

FIG. 1 depicts a schematic diagram of an example of a system for fabricating active interconnects.

FIG. 2 depicts a schematic diagram of an example of a first method for fabricating an interconnect within a device.

FIG. 3 depicts a schematic diagram of an example of a second method for fabricating an interconnect within a device.

FIG. 4 depicts a schematic diagram of an example of a method for augmenting to a method for fabricating an interconnect within a device.

FIG. 5 depicts an example of a comparison of reduced power dissipation of an active interconnect with respect to a traditional interconnect.

### DETAILED DESCRIPTION

Following below are more detailed descriptions of various concepts related to, and implementations of methods and systems for fabricating switchable interconnects. The various concepts introduced above and discussed in greater detail below may be implemented in any of numerous ways as the described concepts are not limited to any particular manner of implementations. Examples of specific implementations and applications are provided primarily for illustrative purposes.

Some fabrication methods include inserting a device into a vertical via. However, these methods typically require a plurality of steps to insert the device (e.g., interrupting the existing system, complex multi-step fabrication, performing planarization, etc.). Some devices that can be inserted into a vertical via are able to reconfigure an integrated circuit. However, such approaches can require a large amount of space to avoid disrupting circuit configurations. Such devices fundamentally alter the footprint necessary within the semiconductor component well beyond that used for a traditional vertical via. For example, some reconfigurable circuits (such as Field-Programmable Gate Arrays (FPGAs) and Erasable Programmable Read-Only Memories (EPROMs)) may require a wire connected to a switch with another wire extending from the switch to change the connections between various parts of the circuit. Other examples (such as cross-bar arrays) require a dedicated region of the chip comprising multiple resistive elements and ancillary circuits for writing and reading the array. Some specific instances of cross-bar arrays (such as 1T1R crossbar arrays) require the presence of another device like a transistor to select an alter the value of a specific element.

This physical constraint and spacing demand is further complicated and undesirable for certain integrated circuit uses. For example, some integrated circuits operate under extreme conditions and include devices for computing and on chip processing. However, computing under these conditions is challenging and can result in device and/or system failure due to a large amount of current being passed through the integrated circuit.

Systems and methods as described herein relate to the development of reconfigurable, resilient architectures for on-chip processing based on active interconnects. Systems and methods in accordance with the present solution provide a vertically integrated approach. This approach allows for various implementations, spanning from fundamental new approaches to material synthesis to innovations in digital architecture design. For example, the active interconnects are building blocks for these architectures, where novel nanoscale devices are embedded into vias to both reconfigure the connectivity and flow of information. The nanoscale devices also act as sensing tools to provide the architectures with an additional level of introspection. The integration of the present solution does not occupy any additional volume of typical vertical vias. As such, implementing the present solution does not require any modification of subsequent manufacturing steps (such as the redesign of new masks, the use of chiplets, or any type of wafer-to-wafer bonding) outside the proposed methodology, as the physical spacing and layout of the integrated chip is retained aside from the described change within the vias. Thus, the present solution is fully compatible with existing, mature semiconductor processes

Systems and methods as described herein have an evolving connectivity that can respond to external inputs and device failure and can help detectors adapt to degradation under extreme environments. These new architectures maximize the chances for the device to recover from localized damage and degradation.

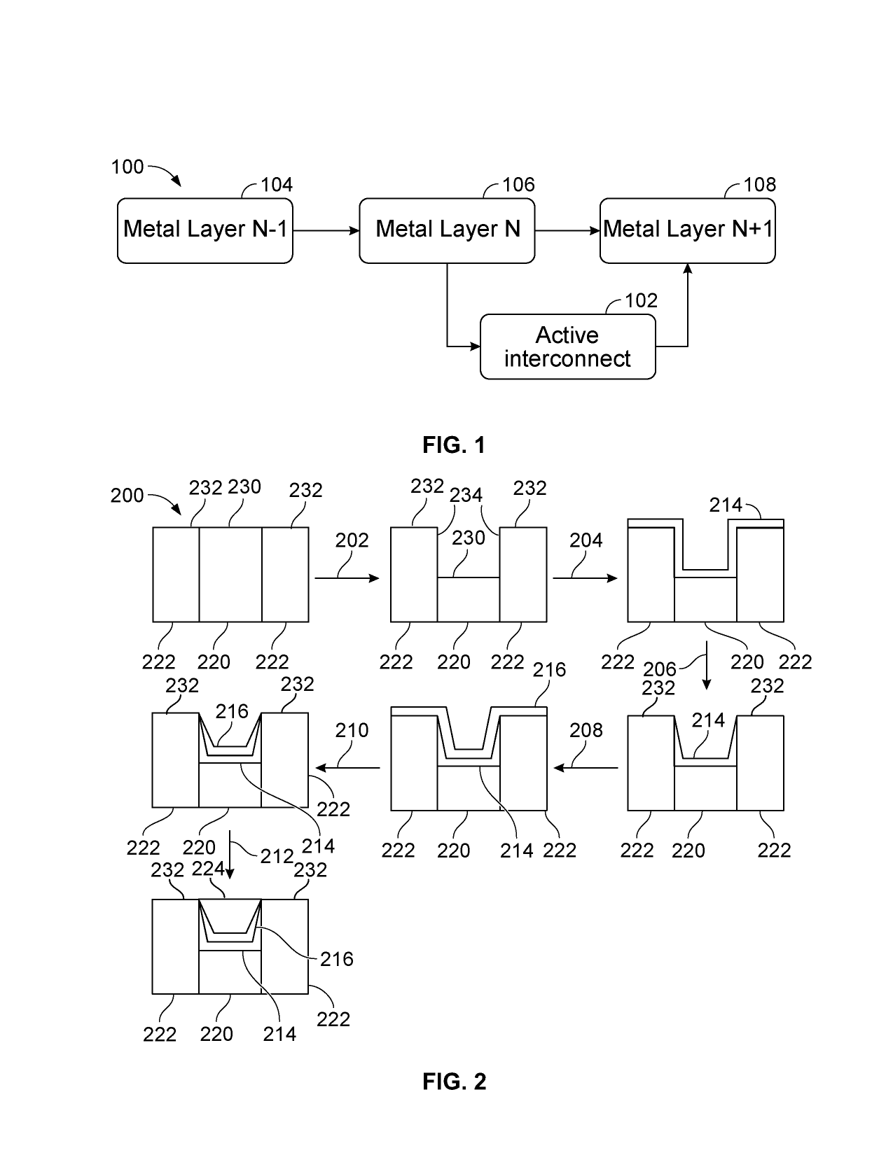

FIG. 1 depicts a flow diagram of a process 100 for integrating an active, switchable interconnect within an electronic component (e.g., chip, semiconductor component), according to an example embodiment. The electronic component includes one or more metal layers, shown as metal layer N-1 104, metal layer N 106, and metal layer N+1 108. Metal layer N 106 may be positioned between metal layer N-1 104 and metal layer N+1 108 in the electronic component. The process 100 includes integrating one or more interconnects, shown as active interconnect 102, between layers of the electronic component. For example, as shown in FIG. 1, the active interconnect 102 may be positioned between metal layer N 106 and metal layer N+1 108.

The one or more metal layers 104, 106, 108 can be separated from each other by one or more insulating layers, including, but not limited to, interlayer dielectrics (ILDs). A plurality of vertical vias (e.g., vias) are positioned within the ILDs. In other words, the vias can be small, metal-filled holes extending through the ILDs between proximate metal layers 104, 106, 108. The vias are configured to electrically couple (e.g., connect, integrate, etc.) the one or more metal layers 104, 106, 108 of the electronic component. The metal layers 104, 106, 108 can also represent layers of an interposer or packaging element, such as structures used with through silicon vias. In these cases, the material between the metal layers 104, 106, 108 can be a semiconductor or a partially conducting material, insulated from the metal layers 104, 106, 108 by one or more dielectric layers. The active interconnects 102 are designed to be compatible with existing metallization approaches, such as those used in semiconductor manufacturing.

One or more nanoscale devices (e.g., components), hereby referred to as devices, can be formed (e.g., incorporated) within the vias that electrically couple the one or more metal layers 104, 106, 108. The active interconnect 102 can enable a variety of functionalities within the electronic component following the formation of one or more devices into the vias. For example, the active interconnects 102 can incorporate one or more devices (e.g., components), including but not limited to memristors, Schottky diodes, metal semiconductor structures, resistances, capacitors, and Josephson junctions. The devices can be adapted to be inserted in various device configurations in a way that is compatible with existing metallization approaches. In some embodiments, the device configuration includes more than two terminals, such as up to a maximum of six terminals. The device configurations can include, but are not limited to, tee configurations, cross configurations, and five- or six-way junctions.

In some implementations, the active interconnect 102 has an active switching component that can allow the active interconnect 102 to act as a nanoscale circuit breaker. The active interconnect 102 can isolate a failing component (e.g., section, part, device) of an integrated circuit (IC) within the electronic component. Responsive to a surge of current (e.g., excessive current due to a failing component), the active interconnect 102 can interrupt and stop the flow of current in the electronic component. This functionality can protect the rest of the IC from damage. For example, the failure of a component to due excessive current typically results in a hard upset (e.g., a failure that is typically irreversible); however, the isolation of the faulty part, using the active interconnect 102, can prevent permanent damage to the rest of the IC.

In some implementations, the active interconnect 102 can stop the flow of current automatically. For example, the active interconnect 102 can include one or more sensors to perform current-induced switching. Responsive to the one or more sensors detecting at least a threshold amount of current (e.g., indicating a surge), the active interconnect 102 can “switch on” and interrupt the flow of current.

In some implementations, the active interconnect 102 can reconfigure the IC within the electronic component. The active interconnect 102 can act as a switch to pass a pulse of current (e.g., or voltage) to interrupt a connection between a first part of the IC and a second part of the IC. This can be done in a reversible manner, meaning the connection can be re-established (e.g., or modified) as needed. Additionally, the IC can be reconfigured using the active interconnect 102 without taking up additional space in the IC layout. The active interconnect 102 can reconfigure the IC by altering a path of current (e.g., through specific current pulses) within the IC.

One or more architecture-level constraints can be provided for the electronic component in terms of current thresholds for interconnect switching, radiation damage, operating voltage, signal propagation delays, etc. required to operate at a given frequency and technology node. The active interconnect 102 can provide one or more sensing modalities to the electronic component. The one or more sensing modalities can use thermal and/or electrical signatures from the active interconnect 102 that can be leveraged by introspective architectures. The one or more sensing modalities can allow for an additional level of introspection in which the electronic component can monitor and adjust itself. Additionally, one or more connections between atomistic simulations of the heterostructures in the active interconnect 102 and circuit-level simulations can provide architecture-level constraints, ensuring optimal performance and reliability.

In some implementations, the device to be inserted into the active interconnect 102 can include one or more layers of materials. The one or more layers of material can be made of various metals, including but not limited to, copper, aluminum, tungsten, molybdenum, ruthenium, platinum, gold, silver, transparent conducting oxides, or superconducting interconnects such as niobium, tantalum, and their nitrides. In some implementations, the use of devices made of materials (e.g., such as gallium oxide) which can handle high amounts of current and high temperatures is advantageous.

In some implementations, the one or more layers of materials can include materials whose electrical properties change with current. The selection of these materials can be advantageous due to the electrical properties of these materials. For example, responsive to a current spike, these materials become less conductive (e.g., more restrictive), so that the current interrupts itself and stops (e.g., almost stops, slows down). The selection of these materials enables the functionalities of the active interconnect 102 to operate with higher efficiency, such as the reconfigurability and isolation functionalities.

In some implementations, the fabrication of the active interconnect 102 is advantageous for being incorporated into systems under extreme conditions (e.g., under high currents, temperature, irradiation, etc.). Examples of extreme systems include, but are not limited to, high radiation environments, detectors for high energy physics environments, nuclear reactors, etc. The active interconnect 102 can be useful in these applications because extreme systems typically pass a high amount of current and as such, are at a higher risk for failure and degradation.

In some implementations, following the fabrication of the active interconnect 102 into an electronic component, the inserted devices (e.g., components) are fully encapsulated by the vias. This ensures the inserted devices will not affect other processing aspects (e.g., post-processing) of the electronic component. Thus, the active interconnects 102 can be integrated into an existing electronic component without requiring significant changes to the existing electronic component. FIG. 2 is a diagram showing a method 200 for forming a functional device (e.g., active interconnect 102) within an existing device (e.g., electronic component), in accordance with some embodiments of the present disclosure. The functional device comprises one or more layers (e.g., metal layers). The method 200, at step 202, includes partially etching a vertical interconnect (e.g., metal interconnect, vertical via), shown as interconnect 220, positioned within an interlayer dielectric (ILD), shown as dielectric layer 222. The dielectric layer 222 provides a layer of insulating material and is typically made from materials with high insulating properties. The partial etching includes etching a base surface of the interconnect 220, shown as base interconnect surface 230 to remove a layer (e.g., of metal) from the interconnect 220 up to a depth required to fully encapsulate a functional device (e.g., an active interconnect 102) within the interconnect 220. After the interconnect 220 has been etched, base interconnect surface 230 is lower relative to a base surface of the dielectric layer 222, shown as base dielectric surface 232. The partial etching can include a blanket etching process, a selective etching process, or a combination of both. The blanket etching process can include applying a mask to the base dielectric surface 232 to protect the dielectric layer 222 from being etched. In this process, this ensures that only the base interconnect surface 230, since it is exposed, is etched. A selective etching process can include applying one or more chemicals, used for etching, to the base interconnect surface 230. The one or more chemicals may be configured (e.g., comprised) to selectively react with the interconnect 220.

This process at step 202 is particularly advantageous for encapsulating two-terminal devices (e.g., memristors, Schottky diodes, resistors, capacitors, etc.) within the interconnect 220, because an exact vertical position of the two-terminal device (e.g., device) is not critical within the interconnect 220if the device is contained within a desired range. The desired range can be defined by delta and h - (delta + w), where delta is a safety factor to ensure full device encapsulation within interconnect 220, w is a final device thickness, and h is a total height of the interconnect 220. For example, if a device thickness is 20nm (w = 20nm), a total height of the vertical via is 100nm (h = 100nm), and the safety factor is 20nm (delta = 20nm), etch rates (e.g., the speed at which the metal layer is etched) across the wafer can vary up to factor of 2 while ensuring that all devices are fully encapsulated.

The method 200, at step 204, includes the deposition of a first layer 214 to the base interconnect surface 230, sidewalls 234 of the interconnect 220, and the base dielectric surface 232. The deposition of the first layer 214 can be enabled through a conformal process, such as atomic layer deposition (ALD) or chemical vapor deposition (CVD). Such conformal deposition processes include the formation of a non-volatile decomposition product as a solid material that accumulates on the substrate in the form of a thin film. Deposition of one or more layers, with etching or partial removal between some or all of the depositions, allows for formation of a layered structure within the interconnect 220. Using ALD for deposition of the first layer 214 requires exposing the base interconnect surface 230, sidewalls 234, and the base dielectric surface 232 to gaseous species that exhibit limited reactivity. ALD can be enabled by sequentially exposing the surface of the base interconnect surface 230, sidewalls 234, and the base dielectric surface 232 to one or more precursors (e.g., such as trimethylgallium and water for gallium oxide). The growth during each exposure is self-limited, and this leads to a homogeneous film (e.g., first layer 214). ALD can be advantageous to the method 200 because it coats the base interconnect surface 230 evenly and the growth of the first layer 214 is self-limiting. For implementations utilizing CVD, ensuring that the sticking probability is low is critical in order to ensure conformality. This can be achieved by selecting processes with intrinsically low sticking probability, for instance by promoting site-blocking either by the adsorbed precursor or growth inhibitors. In general, the depth at which the layer can be conformally coated will be limited by the sticking probability of the CVD process.

The method 200, at step 206, includes an etching back process of the first layer 214. For example, a part of the first layer 214 that was deposited to the base dielectric surface 232 in step 204 is etched (e.g., selectively removed). Etching back the first layer 214 can be enabled by etching a surface layer of the first layer 214, or by penetrating a certain length within the interconnect 220. The latter process results in a plug structure on the bottom of the interconnect 220. This methodology at step 206 is advantageous as it results in a desired structure (e.g., the structure of the interconnect after step 206), without the use of any lithographic steps.

The method 200, at step 208, includes the deposition of a second layer 216 to a surface of the first layer 214 and to the base dielectric surface 232. The deposition of the second layer 216 can be enabled through a conformal process. The conformal process to deposit the second layer 216 can include a same technique(s) as the conformal process used to deposit a first layer 214 at step 204. For example, the deposition of the second layer 216 can be enabled via atomic layer deposition (ALD) or chemical vapor deposition (CVD).

The method 200, at step 210, includes etching (selectively removing) the at least the portion of the second layer 216 that was deposited to the base dielectric surface 232 in step 208220. The etching back process at step 210 can include a same technique(s) as the etching back process used to etch a first layer 214 at step 206. For example, the etching back process at step 210 can be enabled by etching a surface layer of the second layer 316, or by penetrating a certain length within the interconnect 220. This etching back process can ensure that no materials from the first layer 214 and/or the second layer 216 are present at or near a base surface of the dielectric layer 222, such that the materials within the interconnect 220 are fully encapsulated (e.g., sufficiently below the base surface of the dielectric layer 222). This allows the materials of the first layer 214 and/or the second layer 216 to be isolated to prevent contact and/or interaction with materials outside of the interconnect 220.

The method 200, at step 212, includes depositing a capping layer 224 on a surface of the second layer 216, thereby encapsulating the first layer 214 and the second layer 216 within the interconnect 220. In other words, the interconnect 220 can be refilled to fully encapsulate the device (the first layer 214 and the second layer 216). The capping layer 224 may comprise conductive material, which can be advantageous for establishing electrical connections between various metal layers of the IC. In some implementations, it is advantageous for the capping layer 224 to be comprised of a same metal that the interconnect 220 is comprised of to ensure the device (e.g., deposited layers) is fully encapsulated within a metallization layer. For example, in the case where the device is comprised at least partly of copper, the interconnect 220 can be refilled via the redeposition of a copper seed layer, followed by copper electrodeposition. The metallization layer is the same size following the formation of the encapsulated device within the interconnect 220, emphasizing the space saving efficiency of the method 200. After depositing the capping layer 224, a height of the interconnect 220 may be substantially a same as a height of the interconnect 220 prior to the formation of the functional device (e.g., deposited layers) within the interconnect 220.

In some implementations, the steps of method 200 to add a layer (depositing and subsequently etching back the layer) can be applied a set amount of times in order to apply a set amount of layers. In some implementations, only a single layer is deposited and subsequently etched back resulting in one layer being applied in method 200, based on specific electrical requirements and/or characteristics of the one or more devices to be encapsulated (e.g., formed) within the interconnect 220. For example, a single layer may be applied for the creation of Josephson junctions, capacitors, and/or resistors, which can only require one layer.

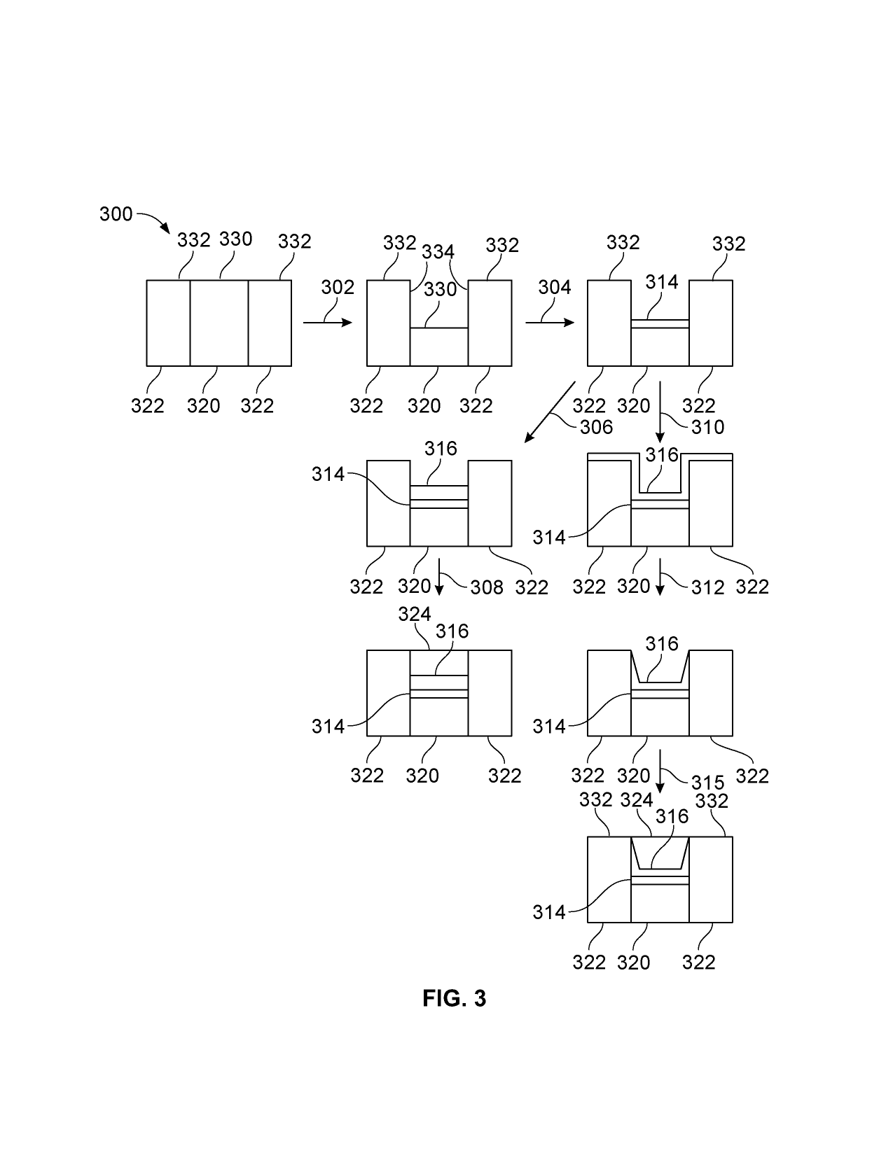

FIG. 3 is a diagram showing a method 300 for forming (e.g., fabricating) a functional device (e.g., active interconnect 102) within an existing device (e.g., electronic component) using area selective deposition processes, in accordance with some embodiments of the present disclosure. In some implementations, the method 300 describes an alternative process to method 200, such that either method 200 or method 300 may be implemented to form a functional device within an existing device.

The method 300, at step 302, includes the partial etching of a vertical interconnect (e.g., metal interconnect, vertical via), shown as interconnect 320, positioned within an interlayer dielectric (ILD), shown as dielectric layer 322. In some implementations, the metal interconnect 320 and the dielectric layer 322 may be the same as the interconnect 220 and the dielectric layer 222 respectively. The partial etching process at step 302 can be a same type as the partial etching process at step 202. For example, the partial etching process at step 302 can include a same technique(s) as the partial etching process at step 202 of method 200, such as utilizing a blanket etching process, a selective etching process, or a combination of both. The partial etching can include etching a base surface of the interconnect 320, shown as base interconnect surface 330 to remove a layer (e.g., of metal) from the interconnect 320 up to a depth required to fully encapsulate a functional device (e.g., an active interconnect 102) within the interconnect 320.

The method 300, at step 304, includes the deposition of a first layer 314 to base interconnect surface 330. The first layer 314 can be a same type as the first layer 214. For example, the first layer 314 can include a same material(s) as first layer 214. The deposition of a first layer 314 can be enabled using a selective deposition process that is selective towards growth on metals. The selective deposition process can include, but is not limited to, a single area selective deposition process, a combination of a selective process involving growth and etching steps, or a sequence of two selective depositions.

In some implementations, the selective deposition process can include the use of small molecule inhibitors. The small molecule inhibitors are configured to selectively absorb on the sidewalls 334 of the interconnect 320 (e.g., with respect to the bottom surface), therefore allowing selective deposition on a base surface of the interconnect 320 to occur, while fully (e.g., almost fully, partially) blocking growth on the (e.g., nitride, oxide) sidewalls 334. Examples of the small molecule inhibitors include, but are not limited to, bidentate and polydentate moieties (such as acetylacetone) together with the use of heteroleptic precursors (such as dimethylaluminum alkoxide, dimethylgallium alkoxide or dimethylindium alkoxide).

For example, the sequence of two selective depositions may include a first selective deposition which deposits a deposition-inhibiting material primarily in a specific area (e.g., the sidewalls 334) of the interconnect 320. This first selective deposition can enhance the absorption of small molecule inhibitors (e.g., small molecules that inhibit deposition) at the sidewalls 334. The second selective deposition of the two selective depositions occurs after the first deposition. The second selective deposition deposits the first layer 314 on the base surface of the interconnect 320. The first selective deposition enables the first layer 314 to be selectively deposited in areas where the small molecule inhibitors are not present (e.g., at the base surface of the interconnect 320). Using a selective deposition process can be advantageous by sidestepping the need of undergoing an etching process, such as the etching back process as described in step 210 of method 200.

In some implementations, the first layer 314 can be deposited through a conformal process, followed by the etching back of the first layer 314. The conformal process to deposit the first layer 314 can include a same technique(s) as the conformal process used to deposit a first layer 214 at step 204 of method 200, such as using ALD or CVD. Then, the first layer 314 can be etched back using a same technique(s) as the etching back process used to etch back a first layer 214 at step 206 of method 200.

Following step 304, the method 300 can proceed with one of steps 306-308 or steps 310-314 to deposit a second layer 316 to a surface of the first layer 314. The second layer 316 can be a same type as the second layer 216. For example, the second layer 316 can include a same material(s) as second layer 216.

Referring to steps 306-308, the method 300, at step 306, includes the deposition of the second layer 316 to a surface of the first layer 314 using a process that is selective towards growth on metals. The process to deposit a second layer 316 at step 306 can be a same process as the process to deposit a first layer 314 at step 304. For example, the process to deposit a second layer 316 can include a same technique(s) as the process to deposit a first layer at step 304, such as using a single area selective deposition process, a combination of a selective process involving growth and etching steps, or a sequence of two selective depositions.

The method 300 at step 308, includes depositing a capping layer 324 on a surface of the interconnect 320, thereby encapsulating the first layer 314 and the second layer 316 within the interconnect 320. The process to deposit a capping layer 324 at step 308 can be a same process as the process to deposit a capping layer 224 on a surface of the interconnect 220 at step 206 of method 200.

Referring now to steps 310-315, the method 300, at step 310, includes the deposition of the second layer 316 to a surface of the first layer 314, the sidewalls 334, and a base surface of the dielectric layer 322, shown as base dielectric surface 332, using a conformal process. The second layer 316 can be deposited on a surface of the first layer 314 through a conformal process. The conformal process to deposit the second layer 316 can include a same technique(s) as the conformal process used to deposit a first layer 214 at step 204 of method 200. For example, atomic layer deposition (ALD) or chemical vapor deposition (CVD) can be used to deposit the second layer 316.

The method 300, at step 312 following step 310, includes an etching back process of a portion of the second layer 316. The etching back process at step 312 can include a same technique(s) as the etching back process used to etch a first layer 214 at step 206 of method 200. For example, the etching back process at step 312 can be enabled by etching a top layer of the second layer 316, or by penetrating a certain length within the vertical vias.

The method 300 at step 315, includes depositing a capping layer 324 on the surface of the second layer 316, thereby encapsulating the first layer 314 and the second layer 316 within the interconnect 320. The process to deposit a capping layer 324 at step 315 can be a same process as the process to deposit a capping layer 224 on a surface of the interconnect 220 at step 206 of method 200.

In some implementations, the steps (e.g., steps 306-308 or steps 310-315) of method 300 to add a layer (depositing and subsequently etching back the layer) can be applied a set amount of times in order to apply a set amount of layers. In some implementations, only a single layer is deposited and subsequently etched back resulting in one layer being applied, such as for the creation of Josephson junctions which only require one layer.

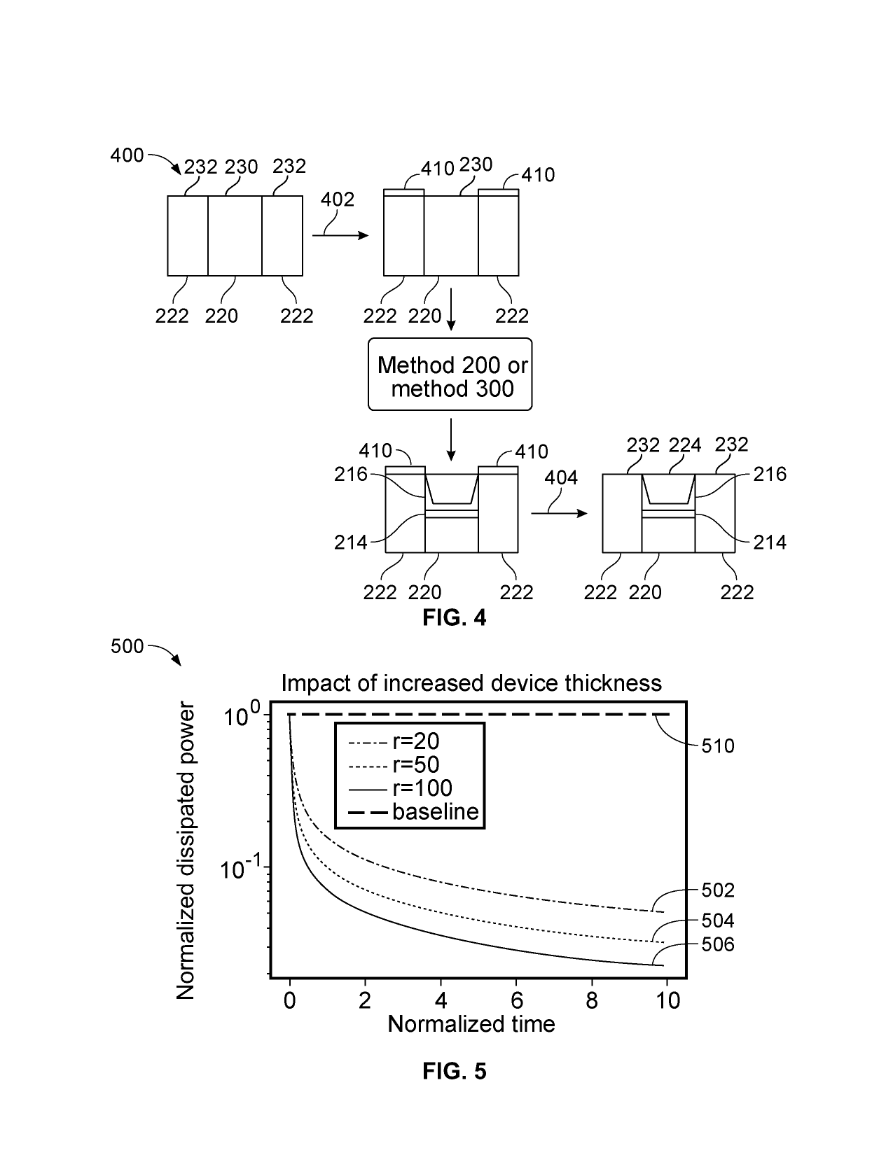

FIG. 4 is a diagram showing a method 400 for augmenting to a method to fabricate an active interconnect, in accordance with some embodiments of the present disclosure. For example, the method 400 includes an augmentation that can be augmented to the method 200 and/or the method 300 for fabricating an interconnect within an existing device. The method 400 includes augmenting method 200 and/or method 300 by depositing a protective layer (e.g., coating, mask, etc.), shown as protective layer 410, as described herein. The protective layer 410 can be deposited to the dielectric layer 222 which can be advantageous to preserve the properties of the dielectric layer 222. Method 400 is described as depositing the protective layer 410 to dielectric layer 222, but it should be understood that in some implementations, the method 400 can be used to deposit the protective layer 410 to dielectric layer 322.

The method 400, at step 402, includes depositing the protective layer 410 on the base surface of the dielectric layer 222 (e.g., base dielectric surface 232) .. The protective layer 410 may be deposited using a standard blanket deposition and then defined using lithography. This can expose the base surface of the interconnect 220 (e.g., base interconnect surface 230) while leaving the dielectric layer 222 protected. This can be advantageous to facilitate depositing one or more layers (e.g., first layer 214, second layer 216) within the interconnect 220, while protecting the dielectric layer 222 (e.g., preserving the properties of the dielectric layer 222)..

In some implementations, the protective layer 410 may alternatively be deposited using a process that is selective towards oxide growth. This process enables the growth of oxide layers on the base surface of the dielectric layer 222, while inhibiting growth of oxide layers on the base surface of the interconnect 220 (e.g., where growth is not desired). The selective oxide growth process can be enabled using various techniques. For example, self-assembled monolayers (SAMs) can be applied to the base surface of the interconnect 220 to block growth. In the example of a copper device, the molecules in the applied SAMs selectively absorb to the copper surface to prevent oxide growth on the base surface of the interconnect 220, while allowing oxide growth on the base surface of the dielectric layer 222. In another example, small molecule inhibitors can be used to achieve the selective growth. In the example of a copper device, small molecule inhibitors that are selective towards copper absorption, such as anyline or 3-hexyne, are used. The small molecule inhibitors attach to the base surface of the interconnect 220 and prevent growth, so the protective layer 410 is selectively deposited on the base surface of dielectric layer 222.

Following the deposition of the protective layer 410, a method to encapsulate a device within the interconnect 220 can be implemented. The method to encapsulate a device can include, but is not limited to, method 200 or method 300 as described above.

Following the formation of the device within the interconnect 220, the method 400, at step 404, includes removing the protective layer 410 from the base surface of the dielectric layer 222 (e.g., base dielectric surface 232).

The methods described above with reference to method 200 and/or method 300 can be used to implement new functionality in a chip without requiring any additional step. One such example comprises the fabrication of active interconnects that can isolate areas of the chip upon unexpected surges in current or voltage, effectively acting as embedded circuit breakers. FIG. 5 compares the normalized dissipated power of devices (e.g., interconnects, vias) of varying thicknesses. At least some of the advantages of such device are shown in FIG. 5: for example, the active interconnect(s), shown as first active interconnect 502, second active interconnect 504, and third active interconnect 506, allows a reduction on the total dissipated power with respect to a conventional device, shown as conventional via 510, by transitioning from a low resistance to a high resistance state upon a local surge of current or voltage. The first active interconnect 502 has a resistance value of r = 20, the second active interconnect 504 has a resistance value of r = 50, and the third active interconnect 506 has a resistance value of r = 100. Moreover, the fabrication steps described above with reference to method 200 and/or method 300 offer a high degree of tunability in terms of the switching kinetics, and low and high resistance states. As exemplified in FIG. 5, the changes in the on/off resistance values, as shown by the varying resistance values of first active interconnect 502, second active interconnect 504, and third active interconnect 506, can help control the relative power dissipation with respect to the conventional via 510. In the example of FIG. 5, the presence of an active interconnect (first active interconnect 502, second active interconnect 504, third active interconnect 506) reduces the power dissipated with respect to a conventional interconnect 510 by at least one order of magnitude. This leads to a reduction in local heating, providing extra time to detect and react to this surge in current, and therefore helping prevent catastrophic damage when devices upstream from the active interconnect fail.

As utilized herein, the terms “approximately,” “about,” “substantially,” and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic. For example, circuit A communicably “coupled” to circuit B may signify that the circuit A communicates directly with circuit B (i.e., no intermediary) or communicates indirectly with circuit B (e.g., through one or more intermediaries).

The term “or,” as used herein, is used in its inclusive sense (and not in its exclusive sense) so that when used to connect a list of elements, the term “or” means one, some, or all of the elements in the list. Conjunctive language such as the phrase “at least one of X, Y, and Z,” unless specifically stated otherwise, is understood to convey that an element may be either X, Y, Z; X and Y; X and Z; Y and Z; or X, Y, and Z (i.e., any combination of X, Y, and Z). Thus, such conjunctive language is not generally intended to imply that certain embodiments require at least one of X, at least one of Y, and at least one of Z to each be present, unless otherwise indicated.

References herein to the positions of elements (e.g., “top,” “bottom,” “above,” “below”) are merely used to describe the orientation of various elements in the FIGURES. It should be noted that the orientation of various elements may differ according to other exemplary embodiments, and that such variations are intended to be encompassed by the present disclosure.

Although the figures and description may illustrate a specific order of method steps, the order of such steps may differ from what is depicted and described, unless specified differently above. Also, two or more steps may be performed concurrently or with partial concurrence, unless specified differently above.

What is claimed is:

1. A method of forming a functional device, comprising:
etching a base surface of an interconnect positioned within a dielectric layer;
depositing a layer on the base surface of the interconnect, sidewalls of the interconnect, and a base surface of the dielectric layer;
removing a portion of the layer from the base surface; and
depositing a capping layer on a surface of the layer, encapsulating the layer within the interconnect.

2. The method of claim 1, wherein the layer is a first layer, and the method further comprises:
after removing the portion of the first layer, depositing a second layer on a surface of the first layer and the base surface of the dielectric layer;
removing a portion of the second layer from the base surface of the dielectric layer; and
depositing the capping layer on a surface of the second layer, encapsulating the first and second layers within the interconnect.

3. The method of claim 1, wherein the base surface of the interconnect is etched using a blanket etching process, a selective etching process, or a combination of a blanket etching and selective etching process.

4. The method of claim 1, wherein the layer is added to the surface of the interconnect using atomic layer deposition (ALD) or chemical vapor deposition (CVD).

5. The method of claim 1, wherein the capping layer and the interconnect are comprised of a same metal.

6. The method of claim 1, further comprising:
before etching the base surface of the interconnect, adding a protective layer to the base surface of the dielectric layer.

7. The method of claim 6, further comprising:
after depositing the capping layer on the surface of the layer, removing the protective layer from the base surface of the dielectric layer.

8. The method of claim 1, wherein the functional device is configured to isolate a part of a circuit.

9. The method of claim 1, wherein the functional device is configured to reconfigure a part of a circuit.

10. A method of forming a functional device, comprising:
etching a base surface of an interconnect positioned within a dielectric layer;
depositing a layer to the base surface using a selective deposition process; and
depositing a capping layer on a surface of the layer, encapsulating the layer within the interconnect.

11. The method of claim 10, further comprising:
before depositing the layer to the base surface of the interconnect, depositing a deposition-inhibiting material to sidewalls of the interconnect.

12. The method of claim 11, further wherein the deposition-inhibiting material comprises small molecule inhibitors.

13. The method of claim 10, wherein the layer is a first layer, and the method further comprises:
after depositing the first layer to the base surface of the interconnect, depositing a second layer on a surface of the first layer; and
depositing the capping layer on a surface of the second layer, encapsulating the first and second layers within the interconnect.

14. The method of claim 13, wherein depositing the second layer on the surface of the first layer further comprises:
depositing the second layer on the base surface of the interconnect, sidewalls of the interconnect, and a base surface of the dielectric layer; and
removing a portion of the second layer from the sidewalls or the base surface of the dielectric layer.

15. The method of claim 13, further comprising:
before depositing the second layer on the surface of the first layer, depositing a deposition-inhibiting material to sidewalls of the interconnect.

16. The method of claim 10, further comprising:
before etching the base surface of the interconnect, adding a protective layer to a base surface of the dielectric layer.

17. The method of claim 16, further comprising:
after depositing the capping layer on the surface of the layer, removing the protective layer from the base surface of the dielectric layer.

18. A method of forming a functional device, comprising:
adding a protective layer to a base surface of a dielectric layer, wherein an interconnect is positioned within the dielectric layer;
etching a base surface of an interconnect positioned within a dielectric layer;
depositing a layer to the base surface of the interconnect using one of a (a) conformal process or (b) a selective deposition process;
depositing a capping layer on a surface of the layer, encapsulating the layer within the interconnect; and
removing the protective layer from the base surface of the dielectric layer.

19. The method of claim 18, wherein the layer is a first layer, and the method further comprises:
after depositing the first layer to the base surface of the interconnect, depositing a second layer on a surface of the first layer; and
depositing the capping layer on a surface of the second layer, encapsulating the first and second layers within the interconnect.

20. The method of claim 19, wherein the second layer is deposited using one of a (a) conformal process or (b) a selective deposition process.
